(19) United States
(12) Patent Application Publication
(10) Pub. No.: US 2006/0054942 A1
(43) Pub. Date: Mar. 16, 2006

(54) Light emitting device

(76) Inventor: Seiji Nakahata, Itami-shi (JP)

Correspondence Address: MCDERMOTT WILL & EMERY LLP, 600 13TH STREET, N.W., WASHINGTON, DC, 20005-3096, US

(21) Appl. No.: 10/522,829

(22) PCT Filed: May 31, 2004
(86) PCT No.: PCT/JP04/07873

§ 371 Date: Jan. 31, 2005

(30) Foreign Application Priority Data
Jun. 18, 2003 (JP) 2003-173465

(51) Int. Cl. H01L 31/112

(52) U.S. Cl. 257/257

(57) ABSTRACT

A light emitting device which has increased light emitting amount without changing its size is provided. The light emitting device is characterized in that a semiconductor layer 30 is formed on an uneven surface 1a of an uneven substrate 1. The light emitting device of the invention can be configured such that the uneven substrate and the semiconductor layer are both made of AlₓGa_{y}In_{1-x-y}N (0≦x, 0≦y, x+y≦1); each of the planes forming the uneven surface of the uneven substrate has at least one plane index selected from among (11-2L) and (1-10L) in which L represents an integer from 1 to 4; and the angle formed between each of the planes forming the uneven surface of the uneven substrate and the base plane is from 35° to 80°.

### TECHNICAL FIELD

The present invention relates to a light emitting device that can emit a large amount of light.

### BACKGROUND ART

A light emitting device for three primary colors: “blue”, “green” and “red” of visible light can be fabricated by using a group III nitride semiconductor. For example, the formation of an amorphous buffer layer on a sapphire substrate at low temperature, and then, a group III nitride semiconductor crystal grown on the thus-formed amorphous buffer layer has been proposed (for example, Shibata, “Fabrication of LED Based on III-V Nitride and its Applications”, Journal of the Japanese Association for Crystal Growth, vol. 29, No. 3, pp. 283 to 287, Sep. 20, 2002).

However, since it uses the sapphire substrate as a substrate, even when a group III nitride semiconductor crystal is epitaxially grown, only crystals of low quality having a large defect density can be obtained. Further, since the sapphire substrate is an insulator, there has been a problem in a resultant large size light emitting device.

In order to solve the aforementioned problem, it has been proposed that a group III nitride semiconductor crystal be grown on a substrate by using a substrate of a group III nitride semiconductor such as n-GaN (for example, Nishida, “AlGaN-based Ultraviolet Light Emitting Diodes”, Journal of the Japanese Association for Crystal Growth, vol. 29, No. 3, pp. 288 to 295, Sep. 20, 2002).

### DISCLOSURE OF THE INVENTION

At present, a sufficient light emitting intensity can not be obtained even by using the aforementioned light emitting device. Under these circumstances, an object of the present invention is to provide a light emitting device in which a light emitting amount is increased without changing the size of the light emitting device.

In order to attain the aforementioned object, the light emitting device according to the present invention is characterized in that a semiconductor layer is formed on an uneven surface of an uneven substrate. On this occasion, the uneven substrate can comprise AlₓGa_{y}In_{1-x-y}N (0≦x, 0≦y, x+y≦1); each of the planes forming the uneven surface of the uneven substrate has at least one plane index selected from among (11-2L) and (1-10L) in which L represents an integer of from 1 to 4; and the angle formed between each of the planes forming an uneven upper surface of the uneven substrate and the base plane can be from 35° to 80°.

### BRIEF DESCRIPTION OF DRAWINGS

FIG. 1 shows a schematic cross-sectional diagram of a light emitting device according to the present invention;

FIG. 2 shows a schematic cross-sectional diagram of a conventional light emitting device;

FIG. 3 is a schematic perspective diagram of an uneven substrate to be used in the present invention;

FIG. 4 is a schematic perspective diagram of another uneven substrate to be used in the present invention; and

FIG. 5 is a schematic perspective diagram of a conventional substrate.

### BEST MODE FOR CARRYING OUT THE INVENTION

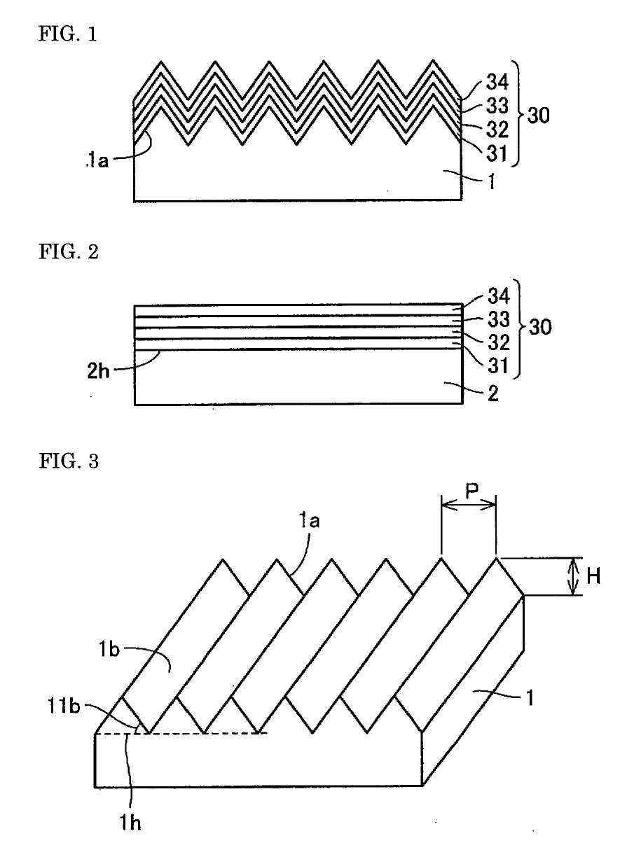

In one light emitting device according to the present invention, in referring to FIG. 1, a semiconductor layer 30 is formed on an uneven surface 1a of an uneven substrate 1. By using such uneven substrate 1 as described above, the surface area of the semiconductor layer 30 for light emission can be large and, accordingly, the light emitting amount of the light emitting device becomes large.

On the other hand, in a conventional light emitting device, in reference to FIG. 2, the semiconductor layer 30 is formed on a planar surface 2h of a plane substrate 2. Namely, in reference to FIGS. 1 and 2, since the semiconductor layer 30 of the light emitting device according to the present invention is formed on the uneven surface 1a of the uneven substrate 1, a surface area thereof becomes larger than that of the semiconductor layer 30 formed on the planar surface 2h of the plane substrate 2. In this case, since the semiconductor layer 30 has a constant light emitting amount per unit surface area, by allowing the surface area of the semiconductor layer 30 to be large in such a manner as described above, the light emitting amount can be large without changing the size of the light emitting device.

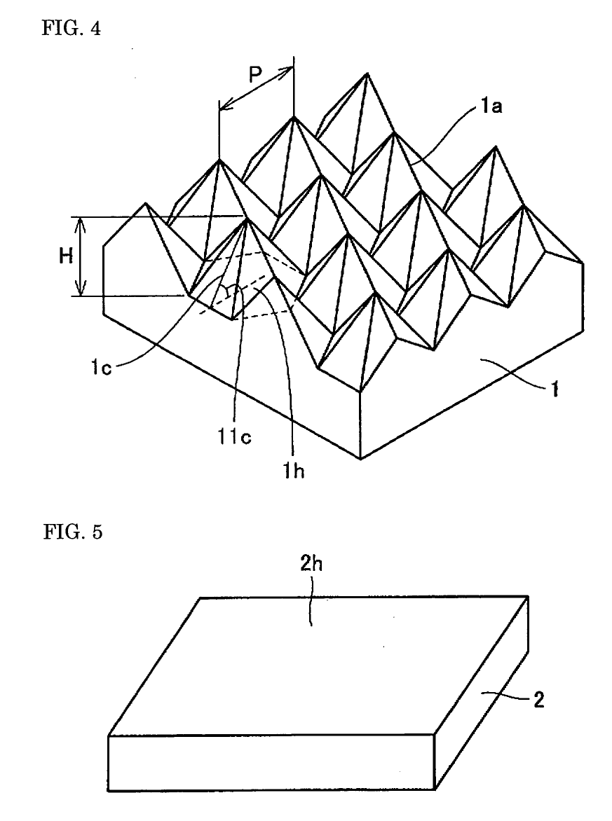

On this occasion, in reference to FIGS. 3 and 4, the surface shape of the uneven surface 1a of the uneven substrate 1 is not particularly limited and, for example, the uneven surface 1a having triangular peak portions and triangular valley portions as shown in FIG. 3 is permissible, or the uneven surface 1a in a polyhedral pyramidal shape where one peak region is delineated by a broken line, shown in FIG. 4, is permissible.

Further, peak-valley pitch (horizontal distance between a projection portion and an adjacent projection portion) P in the uneven surface 1a of the uneven substrate 1 and peak-valley height (vertical distance between a recess portion and a projection portion) H are not particularly limited. However, pitch P is preferably from 1 μm to 3000 μm and height H is preferably from 0.1 μm to 3000 μm. When the peak-valley pitch P is less than 1 μm or more than 3000 μm, it becomes difficult to obtain a uniform epitaxial crystal. When the uneven height H is less than 0.1 μm, light emitting area becomes small, while, when it is more than 3000 μm, it becomes difficult to obtain a uniform epitaxial crystal. Under these circumstances, the peak-valley pitch P is more preferably from 1 μm to 500 μm and the peak-valley height H is more preferably from 4 μm to 1500 μm.

In the light emitting device according to the present invention, the uneven substrate and the semiconductor layer each preferably comprise AlₓGa_{y}In_{1-x-y}N (0≦x, 0≦y, x+y≦1). By constructing the semiconductor layer from AlₓGa_{y}In_{1-x-y}N (0≦x, 0≦y, x+y≦1) which is a group III compound, the light emitting device for three primary colors: “blue”, “green” and “red” of visible light or “ultraviolet” can be fabricated. Further, also in regards to the substrate, by using AlₓGa_{y}In_{1-x-y}N (0≦x, 0≦y, x+y≦1) here as in the semiconductor layer, a semiconductor layer of good quality can be grown. Still further, the chemical composition of the substrate, that of the semiconductor crystal and a combination of these compositions are not particularly limited and, from the standpoint of obtaining semiconductor layer of good quality, the chemical composition of the substrate and that of the semiconductor layer are favorably similar.

Further, in reference to FIGS. 3 and 4, in the light emitting device according to the present invention, it is preferable that each of planes 1b and 1c forming the uneven surface of the uneven substrate has at least one plane index selected from among (11-2L) and (1-10L) in which L represents an integer of from 1 to 4. In the case in which AlₓGa_{y}In_{1-x-y}N (0≦x, 0≦y, x+y≦1) is used in the substrate and the semiconductor layer, since an AlₓGa_{y}In_{1-x-y}N (0≦x, 0≦y, x+y≦1) crystal has hexagonal symmetry, there exist six equivalent planes with the same index (11-2L) or (1-10L). On this occasion, L denotes an integer from 1 to 4. Therefore, by using the uneven substrate 1 having the uneven surface 1a comprising such planes as described above, a semiconductor layer of a three-dimensional structure can be formed and, accordingly, the surface area of the semiconductor layer can be large. On this occasion, in the case in which the uneven substrate comprises AlₓGa_{y}In_{1-x-y}N (0≦x, 0≦y, x+y≦1), a hexagonal pyramid or a triangular pyramid is often the polygonal pyramid formed on the uneven surface 1a as shown in FIG. 4.

Further, in reference to FIGS. 3 and 4, in the light emitting device according to the present invention, angles φ 11b and 11c formed between each of the planes 1b and 1c forming the uneven surface 1a of the uneven substrate 1 and a base plane 1h are preferably from 35° to 80°, respectively. In the case in which the AlₓGa_{y}In_{1-x-y}N crystal is used as the uneven substrate, a stable peak having an angle of over 80° seldom exists. Further, when the aforementioned angle is less than 35°, the surface area of the semiconductor layer is scarcely increased at all. Here, the base plane 1h denotes a plane perpendicular to a vector in a thickness direction of the uneven substrate 1 and is a plane parallel to a planar surface in a conventional plane substrate.

The AlₓGa_{y}In_{1-x-y}N (0≦x, 0≦y, x+y≦1) crystal constituting the substrate has a wurtzite-type (hexagonal) crystalline structure and, accordingly, has hexagonal symmetry. Each angle φ formed between each of the planes forming the uneven surface and the angle base plane can be computed by Equation (1) as described below. On this occasion, (h₁k₁−(h₁+k₁)l₁) denotes a plane index of each of the planes forming the uneven surface; (h₂k₂−(h₂+k₂)l₂) denotes a plane index of a base plane (for example, (0001)); a denotes a axis length; b denotes b axis length; and c denotes c axis length. Further, the plane index of each of the planes forming the uneven surface of the uneven substrate and the base plane can be obtained by an X-ray diffraction (hereinafter, referred to as “XRD”) method.

$$\begin{matrix}Equation 1 : & \\ cos ϕ = \frac{{h}_{1} {h}_{2} + {k}_{1} {k}_{2} + \frac{1}{2} ( {h}_{1} {k}_{2} + {h}_{2} {k}_{1} ) + \frac{3 {a}^{2} {l}_{1} {l}_{2}}{4 {c}^{2}}}{{( ( {h}_{1}^{2} + {k}_{1}^{2} + {h}_{1} {k}_{1} + \frac{3 {a}^{2} {l}_{1}^{2}}{4 {c}^{2}} ) \\ ( {h}_{2}^{2} + {k}_{2}^{2} + {h}_{2} + {k}_{2} + \frac{3 {a}^{2} {l}_{2}^{2}}{4 {c}^{2}} ) )}^{\frac{1}{2}}} & ( 1 )\end{matrix}$$

### EXAMPLES

Hereinafter, a light emitting device according to the present invention will be described in detail with reference to the embodiments.

### Example 1

By using a GaN substrate which had an uneven surface 1a having a peak-valley pitch P of 200 μm and a peak-valley height H of 190 μm, as shown in FIG. 3, and in which the plane index of each of the planes 1b forming the aforementioned uneven surface 1a was (1-101), an n-GaN layer 31 of 5 μm, an In_{0.2}Ga_{0.8}N layer 32 of 3 nm, a p-Al_{0.2}Ga_{0.8}N layer 33 of 60 nm and a p-GaN layer 34 of 150 nm were grown on the uneven surface of the aforementioned GaN substrate in this order by a Metal Organic Chemical Vapor Deposition (hereinafter, referred to as “MOCVD”) method, to thereby obtain a light emitting device as shown in FIG. 1. A light emitting intensity of the aforementioned light emitting device was measured by using a spectrograph. It has been found that the peak wavelength of a light emitting spectrum of this light emitting device was 470 nm and the light emitting intensity of this light emitting device was 1.9 where the light emitting intensity of Comparative Example 1 to be described below was defined as 1.0. Further, in Example 1, the semiconductor layer was grown on the uneven surface of the uneven substrate by using the MOCVD method. The semiconductor layer can also be grown by using various types of other methods such as Vapor Phase Epitaxy (hereinafter, referred to as “VPE”) method and Molecular Beam Epitaxy (hereinafter, referred to as “MBE”) method.

### Comparative Example 1

By using a GaN substrate which has a planar surface 2h (since being planar, peak-valley pitch P is 0 μm and peak-valley height H is 0 μm) as shown in FIG. 5 and in which a plane index of the aforementioned planar surface 2h was (0001), semiconductor layers were grown in the same manner as in Example 1, to thereby obtain a light emitting device as shown in FIG. 2. A light emitting intensity of the aforementioned light emitting device was measured by using a spectrograph. A peak wavelength of a light emitting spectrum of this light emitting device was 470 nm, and then, the light emitting intensity of a blue light emitting device of each of the Examples 1 to 9 was compared with the light emitting intensity of this light emitting device defined as 1.0.

### Examples 2 to 11, Comparative Examples 2 and 3

A light emitting device having a substrate and a semiconductor layer constitution as shown in Tables I to III was fabricated by using MOCVD method, and then, the wavelength of a light emitting spectrum and light emitting intensity thereof were measured. The results are collectively shown in Tables I to III. Further, an angle φ in each of the Tables I to III shows the angle as calculated by Eq. 1 from the plane index of each of the planes forming an uneven surface of an uneven substrate and the plane index (0001) of a base plane.

On this occasion, Examples 1 to 9 and Comparative Example 1 in Table 1 are each an example of a blue light emitting device in which a peak wavelength of a light emitting spectrum is 470 nm and a light emitting intensity of each of the Examples 1 to 9 was indicated as a relative value where the light emitting intensity of Comparative Example 1 was defined as 1.0. Further, Example 10 and Comparative Example 2 in Table II are each an example of a green light emitting device in which the peak wavelength of a light emitting spectrum is 520 nm, and a light emitting intensity of Example 10 was indicated as a relative value where the light emitting intensity of Comparative Example 2 was defined as 1.0; and Example 11 and Comparative Example 3 in Table III are each an example of an ultraviolet light emitting device in which a peak wavelength of a light emitting spectrum is 380 nm, and a light emitting intensity of Example 11 was indicated as a relative value where the light emitting intensity of Comparative Example 3 was defined as 1.0.

TABLE I

| | Comp. | | | | | | | | | |
|---|---|---|---|---|---|---|---|---|---|---|
| | Example | Example | Example | Example | Example | Example | Example | Example | Example | Example |
| | 1 | 1 | 2 | 3 | 4 | 5 | 6 | 7 | 8 | 9 |
| Type of substrate | GaN | GaN | GaN | GaN | GaN | GaN | AlN | AlGaN | InN | InGaN |
| Shape of | | | | | | | | | | |
| substrate | | | | | | | | | | |
| P (μm) | 0 | 200 | 100 | 20 | 50 | 100 | 50 | 20 | 20 | 10 |
| H (μm) | 0 | 190 | 40 | 33 | 40 | 80 | 45 | 19 | 19 | 9 |
| Plane index | (0001) | (1-101) | (11-24) | (11-21) | (11-22) | (11-22) | (1-101) | (1-101) | (1-101) | (1-101) |
| Angle φ (°) | 0 | 62 | 39 | 73 | 58 | 58 | 62 | 62 | 62 | 62 |
| Semiconductor | n-GaN | n-GaN | n-GaN | n-GaN | n-GaN | n-GaN | n-GaN | n-GaN | n-GaN | n-GaN |
| layer | (5000)/ | (5000)/ | (5000)/ | (5000)/ | (5000)/ | (5000)/ | (5000)/ | (5000)/ | (5000)/ | (5000)/ |
| (thickness nm) | In_{0.2}Ga_{0.8} | In_{0.2}Ga_{0.8} | In_{0.2}Ga_{0.8} | In_{0.2}Ga_{0.8} | In_{0.2}Ga_{0.8} | In_{0.2}Ga_{0.8} | In_{0.2}Ga_{0.8} | In_{0.2}Ga_{0.8} | In_{0.2}Ga_{0.8} | In_{0.2}Ga_{0.8} |
| | N(3)/p- | N(3)/p- | N(3)/p- | N(3)/p- | N(3)/p- | N(3)/p- | N(3)/p- | N(3)/p- | N(3)/p- | N(3)/p- |
| | Al_{0.2} | Al_{0.2} | Al_{0.2} | Al_{0.2} | Al_{0.2} | Al_{0.2} | Al_{0.2} | Al_{0.2} | Al_{0.2} | Al_{0.2} |
| | Ga_{0.8}N | Ga_{0.8}N | Ga_{0.8}N | Ga_{0.8}N | Ga_{0.8}N | Ga_{0.8}N | Ga_{0.8}N | Ga_{0.8}N | Ga_{0.8}N | Ga_{0.8}N |
| | (60)/p- | (60)/p- | (60)/p- | (60)/p- | (60)/p- | (60)/p- | (60)/p- | (60)/p- | (60)/p- | (60)/p- |
| | GaN(150) | GaN(150) | GaN(150) | GaN(150) | GaN(150) | GaN(150) | GaN(150) | GaN(150) | GaN(150) | GaN(150) |
| Light emitting | 470 | 470 | 470 | 470 | 470 | 470 | 470 | 470 | 470 | 470 |
| peak wavelength | | | | | | | | | | |
| (nm) | | | | | | | | | | |
| Light emitting | 1.0 | 1.9 | 1.2 | 2.5 | 1.9 | 1.9 | 1.7 | 1.9 | 1.7 | 1.8 |
| intensity ratio | | | | | | | | | | |

TABLE II

| | Comparative | |
|---|---|---|
| | Example 2 | Example 10 |
| Type of substrate | GaN | GaN |
| Shape of substrate | | |
| P (μm) | 0 | 100 |
| H (μm) | 0 | 94 |
| Plane index | (0001) | (1-101) |
| Angle φ (°) | 0 | 62 |
| Semiconductor | n-GaN(5000)/ | n-GaN(5000)/ |
| layer | In_{0.45}Ga_{0.55}N(3)/ | In_{0.45}Ga_{0.55}N(3)/ |
| (thickness nm) | p-Al_{0.2}Ga_{0.8}N(60)/ | p-Al_{0.2}Ga_{0.8}N(60)/ |
| | p-GaN(150) | p-GaN(150) |
| Light emitting | 520 | 520 |
| peak wavelength | | |
| (nm) | | |
| Light emitting | 1.0 | 2.1 |
| intensity ratio | | |

TABLE III

| | Comparative | |
|---|---|---|
| | Example 3 | Example 11 |
| Type of substrate | GaN | GaN |
| Shape of substrate | | |
| P (μm) | 0 | 50 |
| H (μm) | 0 | 47 |
| Plane index | (0001) | (1-101) |
| Angle φ (°) | 0 | 62 |
| Semiconductor | n-GaN(5000)/ | n-GaN(5000)/n- |
| layer | n-Al_{0.2}Ga_{0.8}N(60)/ | Al_{0.2}Ga_{0.8}N(60)/ |
| (thickness nm) | In_{0.02}Ga_{0.98}N(3)/ | In_{0.02}Ga_{0.98}N(3)/ |
| | p-Al_{0.2}Ga_{0.8}N(60)/ | p-Al_{0.2}Ga_{0.8}N(60)/ |
| | p-GaN(150) | p-GaN(150) |
| Light emitting | 380 | 380 |
| peak wavelength | | |
| (nm) | | |
| Light emitting | 1.0 | 1.8 |
| intensity ratio | | |

As shown in Tables I to III, in the light emitting device, in which the semiconductor layer was formed on the uneven surface of the uneven substrate, according to the present invention, the light emitting intensity has been increased from 1.2 time to 2.5 times, regardless of the light emitting peak wavelength, compared with the conventional light emitting device in which the semiconductor layer was formed on the plane substrate.

It is to be understood that embodiments and examples disclosed herein are illustrative and not restrictive in all aspects. The scope of the invention should be determined with reference to the appended claims and not to the above descriptions and is intended to include meanings equivalent to such claims and all such modifications and variations as fall within the scope of such claims.

### INDUSTRIAL APPLICABILITY

As has been described above, in a light emitting device according to the present invention, the light emitting amount can be increased by forming a semiconductor layer on an uneven surface of an uneven substrate, without changing the size of the light emitting device.

1. A light emitting device, being characterized by forming a semiconductor layer on an uneven surface of an uneven substrate.

2. The light emitting device as set forth in claim 1, wherein the uneven substrate and the semiconductor layer comprise AlₓGa_{y}In_{1-x-y}N (0≦x, 0≦y, x+y≦1).

3. The light emitting device as set forth in claim 1, wherein each of the planes forming the uneven surface of the uneven substrate has at least one plane index selected from among (11-2L) and (1-10L), wherein L represents an integer of from 1 to 4.

4. The light emitting device as set forth in claim 2, wherein each of the planes forming the uneven surface of the uneven substrate has at least one plane index selected from among (11-2L) and (1-10L), wherein L represents an integer of from 1 to 4.

5. The light emitting device as set forth in claim 1, wherein the angle formed between each of the planes forming the uneven surface of the uneven substrate and the base plane is from 35° to 80°.

6. The light emitting device as set forth in claim 2, wherein the angle formed between each of the planes forming the uneven surface of the uneven substrate and the base plane is from 35° to 80°.
